(19) United States
(12) Patent Application Publication
(10) Pub. No.: US 2026/0219587 A1
(43) Pub. Date: Jul. 30, 2026

(54) STAGE APPARATUS, SUBSTRATE PROCESSING APPARATUS, ARTICLE MANUFACTURING METHOD, AND CONTROL METHOD OF STAGE APPARATUS

(71) Applicant: CANON KABUSHIKI KAISHA, Tokyo (JP)

(72) Inventors: TOSHIYUKI MYOJO, Tochigi (JP); SHIGEO KOYA, Tochigi (JP)

(21) Appl. No.: 19/457,020

(22) Filed: Jan. 22, 2026

(30) Foreign Application Priority Data
Jan. 28, 2025 (JP) 2025-012293

(51) Int. Cl. G03F 7/00

(52) U.S. Cl. CPC G03F 7/70725

(57) ABSTRACT

A stage apparatus includes a substrate chuck, a supplier configured to supply a gas to a space between a substrate and the substrate chuck, a pin member configured to support the substrate by protruding from a hole formed in the substrate chuck, a driver configured to move at least one of the substrate chuck and the pin member, and a controller configured to control the driver and the supplier based on a control profile, wherein the controller starts first supply of gas by the supplier in a second period during which, after a first period, the driver stops in a state in which the substrate and the pin member are close, and terminates the first supply before the second period ends.

### BACKGROUND

### Field of the Technology

The present disclosure relates to a stage apparatus, a substrate processing apparatus, an article manufacturing method, and a control method of the stage apparatus.

### Description of the related Art

In a substrate processing apparatus used for a manufacturing process of a semiconductor device, a liquid crystal display device, or the like, a substrate chuck for holding (vacuum-holding) a substrate, and lift pins for separating the substrate from the substrate chuck, are used. The smoothness of holding and releasing the substrate by the substrate chuck is related not only to the productivity but also to the wear resistance of each of the substrate and the substrate chuck.

Japanese Patent Laid-Open No. 2019-83286 discloses a technique for supplying the amount of gas corresponding to the maximum capacity of a closed space that is generated when unloading a substrate from a substrate chuck due to the difficulty in separating the outer periphery of the substrate from the substrate chuck.

However, if the gas supply amount between the substrate and the substrate chuck is too large, the substrate laterally shifts with respect to the pin. To the contrary, if the gas supply amount is too small, the chucking force remains between the substrate and the substrate chuck. If the substrate is separated from the substrate chuck in this state, a problem occurs: the substrate chuck wears.

### SUMMARY

Embodiments of the present disclosure provide techniques advantageous in terms of suppression of the lateral shift of a substrate and the wear resistance of a substrate chuck regarding cancellation of the holding of the substrate by the substrate chuck.

The present disclosure in its one aspect provides a stage apparatus including a substrate chuck configured to support a substrate, a supplier configured to supply a gas to a space between the substrate and the substrate chuck, a pin member configured to support the substrate by protruding from a hole formed in the substrate chuck, a driver configured to move at least one of the substrate chuck and the pin member, and a controller configured to control the driver and the supplier based on a control profile, wherein the control profile includes a first period during which, from a state in which the substrate is placed on the substrate chuck, the driver drives so as to make the pin member protrude from the hole and approach the substrate, a second period during which, after the first period, the driver stops in a state in which the substrate and the pin member are close, and a third period during which, after the second period, the driver drives so as to separate the substrate and the substrate chuck, and the controller starts first supply of gas by the supplier in the second period, and terminates the first supply by reducing a supply amount of gas from the supplier before the second period ends.

Features of various embodiments will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing the configuration of a substrate processing apparatus.

FIG. 2 is a view showing the functional configuration of a controller.

FIG. 3 is a view showing an example of the configuration of a substrate stage.

FIG. 4 is a plan view showing an example of a substrate chuck.

FIG. 5 is a view for explaining a substrate transfer operation.

FIG. 6 is a view for explaining a substrate transfer operation.

FIG. 7 is a view showing an example of the drive profile of a fine moving stage.

FIGS. 8A1 to 8A4 are views each for explaining the control during a substrate transfer operation.

FIGS. 8B1 to 8B3 are views each for explaining the control during a substrate transfer operation.

FIG. 9 is a view for explaining a substrate transfer operation.

FIG. 10 is a view for explaining the control during a substrate transfer operation.

FIG. 11 is a view showing an example of the arrangement of a pressure sensor.

FIGS. 12A and 12B are views each for explaining the control during a substrate transfer operation.

FIGS. 13A and 13B are views showing an example of the arrangement of a distance sensor and a load sensor.

FIG. 14 is a view showing an example of the temporal change of the Z deviation during a separation operation.

FIG. 15 is a view showing an example of the Z-direction moving speed during a separation operation.

FIG. 16 is a view showing an example of the configuration of a substrate stage.

FIG. 17 is a plan view showing an example of a substrate chuck.

FIGS. 18A to 18E are views each for explaining an example of the gas supply control.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant descriptions thereof are omitted.

In the embodiments, a substrate processing apparatus that processes a substrate can include a lithography apparatus, a measurement apparatus, an inspection apparatus, and the like. The lithography apparatus is an apparatus configured to form a pattern on a substrate, and the lithography apparatus includes, for example, an exposure apparatus, an imprint apparatus, a planarization apparatus, a rendering apparatus, and the like. The exposure apparatus includes an apparatus that projects the pattern of an original (mask or reticle) to a substrate and exposes the substrate. The imprint apparatus includes an apparatus that molds an imprint material on a substrate with a mold and forms the pattern of the imprint material on the substrate. The planarization apparatus includes an apparatus that planarizes a composition on a substrate using a mold having a flat surface. The rendering apparatus includes an apparatus that renders a pattern on a substrate using a charged particle beam (electron beam, ion beam, or the like). The measurement apparatus is an apparatus configured to measure a substrate, and the measurement apparatus includes, for example, an alignment measurement apparatus used to align an original and a substrate. The inspection apparatus is an apparatus configured to inspect a substrate, and includes, for example, an overlay inspection apparatus that inspects the overlay precision of a pattern formed on a substrate.

### First Embodiment

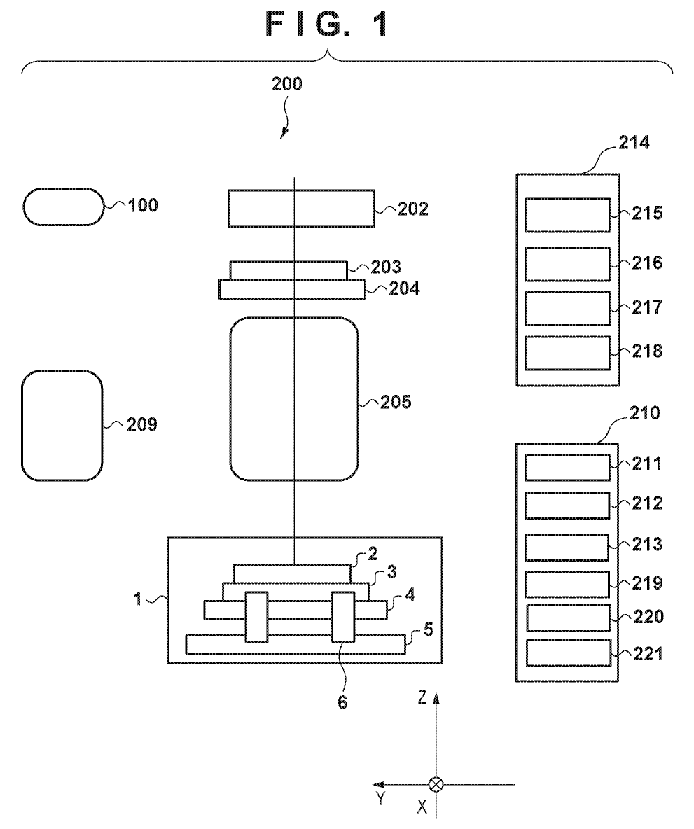

FIG. 1 is a schematic view showing the configuration of an exposure apparatus 200 as a substrate processing apparatus according to the first embodiment. The exposure apparatus 200 is used for a lithography process that is a manufacturing process of a device such as a semiconductor device or a liquid crystal display device. The exposure apparatus 200 is a lithography apparatus that exposes a substrate using an original to transfer the pattern of the original to the substrate, that is, form the pattern on the substrate.

In this specification and the accompanying drawings, directions are indicated in an XYZ coordinate system in which a direction parallel to a plane on which a substrate is arranged is defined as an X-Y plane. Directions parallel to the X-axis, Y-axis, and Z-axis in the XYZ coordinate system are defined as the X direction, the Y direction, and the Z direction, respectively. A rotation about the X-axis, a rotation about the Y-axis, and a rotation about the Z-axis are defined as θX, θY, and θZ, respectively.

As shown in FIG. 1, the exposure apparatus 200 includes a substrate stage 1 (stage apparatus), a controller 100, an illumination optical system 202, an original stage 204, a projection optical system 205, an off-axis scope 209, a substrate conveyance system 210, and an original conveyance system 214.

In the exposure apparatus 200, the illumination optical system 202 illuminates an original 203 with light (exposure light) from a light source. The projection optical system 205 has a function of imaging light traveling from an object plane onto an image plane. The projection optical system 205 projects on a substrate 2 the light having passed through (the pattern of) the original 203, and forms the image of the pattern of the original 203 on the substrate.

The original stage 204 holds the original 203 via an original chuck (not shown) configured to suck and hold the original 203. The original stage 204 is a stage that linearly moves in the X, Y, and Z directions and is driven to rotate in the θX, θY, and θZ directions. The original stage 204 can independently control driving in each direction. The exposure apparatus 200 includes a laser interferometer (not shown) to measure the position of the original stage 204 at high precision. The position of the original stage 204 is decided from the displacement amount of the original stage 204 that is measured by the laser interferometer.

The original conveyance system 214 includes a hand 215, a pre-alignment stage 216, a conveyance robot 217, and a storage 218. The conveyance robot 217 is constituted by an articulated robot. The conveyance robot 217 includes an original holder that holds the original 203, and can drive the original holder to an arbitrary position in the XYZ space. The storage 218 includes a table on which the original 203 is placed, and stores the original 203 conveyed from outside the apparatus. The original 203 stored in the storage 218 is conveyed to the pre-alignment stage 216 by the conveyance robot 217.

In the pre-alignment stage 216, the mark of the original 203 is detected (observed) by a microscope to measure a positional relationship (misalignment of the original 203 with respect to the pre-alignment stage 216) between the original 203 and the pre-alignment stage 216. After the positional relationship between the original 203 and the pre-alignment stage 216 is measured, the hand 215 holds the original 203 on the pre-alignment stage and drives the original 203 along a guide to a position (original supply position) where the original 203 is handed over to the original stage 204. At the original supply position, the hand 215 hands over the original 203 to the original stage 204. The original stage 204 vacuum-sucks and holds the original 203 via the original chuck. Misalignments of the original 203 with respect to the pre-alignment stage 216 in the X, Y, and θZ directions can be corrected by adjusting the position where the original stage 204 receives the original 203.

The substrate conveyance system 210 includes a supply hand 211, a recovery hand 212, a storage 213, a pre-alignment unit 219, a conveyance robot 220, and a temporary table 221. The storage 213 stores the substrate 2. The conveyance robot 220 is constituted by an articulated robot. The conveyance robot 220 includes a substrate holder that holds the substrate 2, and can drive the substrate holder to an arbitrary position in the XYZ space. The conveyance robot 220 picks up the substrate 2 from the storage 213 and places the substrate 2 in the pre-alignment unit 219. In the pre-alignment unit 219, the outer peripheral portion of the substrate 2 is irradiated with light, and the reflected light is detected by a sensor to measure the position of the outer shape of the substrate 2 with respect to the pre-alignment unit 219.

The supply hand 211 is a mechanism configured to transfer the substrate 2 from the pre-alignment unit 219 to the substrate stage 1 (pin members 6 provided on a coarse moving stage 5). The supply hand 211 can vacuum-suck and hold the substrate 2. The recovery hand 212 is a mechanism configured to transfer the substrate 2 from the substrate stage 1 to the temporary table 221. The recovery hand 212 can vacuum-suck and hold the substrate 2. The temporary table 221 is a table configured to temporarily place the substrate 2 recovered from the substrate stage 1 by the recovery hand 212. The conveyance robot 220 cannot directly receive the substrate 2 from the recovery hand 212, and thus the conveyance robot 220 transfers the substrate 2 via the temporary table 221.

The substrate stage 1 includes a fine moving stage 4 and the coarse moving stage 5. The substrate stage 1 vacuum-sucks and holds the substrate 2 via a substrate chuck 3 placed on the fine moving stage 4 and supporting the substrate 2. The fine moving stage 4 is a stage that includes a driver (actuator) for causing the stage to linearly move in the X, Y, and Z directions and be driven to rotate in the θX, θY, and θZ directions. The fine moving stage 4 can independently control driving in each direction. The exposure apparatus 200 includes a laser interferometer (not shown) to measure the position of the fine moving stage 4 at high precision. The position of the fine moving stage 4 is decided from the displacement amount of the fine moving stage 4 that is measured by the laser interferometer.

The pin member 6 is used when receiving the substrate 2 from the supply hand 211 and when transferring the substrate 2 to the recovery hand 212. The pin member 6 can vacuum-suck and hold the substrate 2. In this embodiment, at least three pin members 6 are fixed to the coarse moving stage 5 and provided to stand with respect to a holding surface of the substrate chuck 3 on which the substrate 2 is held. The pin members 6 are fixed to the coarse moving stage 5 and thus driven together with the coarse moving stage 5. Note that three pin members 6 are provided in this embodiment, but the number of pin members 6 is not limited to any specific number as long as they can satisfactorily and stably hold the substrate 2 in accordance with the size, material, and mass of the substrate 2.

The coarse moving stage 5 is a stage that linearly moves in the X and Y directions and is driven to rotate in the θZ direction. The coarse moving stage 5 is controlled to follow the position of the fine moving stage 4 via an actuator, such as a linear motor, based on a distance between the coarse moving stage 5 and the fine moving stage 4 that is measured by, for example, a capacitance sensor.

In an outer space (outer space of the substrate chuck 3) as a space around the substrate stage 1, a temperature-controlled gas is supplied from a gas supply port (not shown) provided in the exposure apparatus 200, and the ambient temperature, humidity, and the like of the substrate stage 1 are maintained at predetermined values. Hereinafter, the outer space of the substrate stage 1 in which the ambient temperature, humidity, and the like of the substrate stage 1 are maintained at predetermined values will be sometimes called a stage space.

The off-axis scope 209 measures the position of the substrate 2 by detecting a mark (alignment mark) provided on the substrate 2 held by the substrate stage 1.

The controller 100 is constituted by an information processing apparatus (computer) including a CPU, a memory, and the like. The controller 100 comprehensively controls the respective units of the exposure apparatus 200 to operate the exposure apparatus 200 in accordance with programs stored in a storage unit. The controller 100 controls, for example, a sequence (exposure sequence) regarding exposure processing of exposing the substrate 2, a sequence (supply sequence) of supplying the substrate 2 to the substrate stage 1, a sequence (recovery sequence) of recovering the substrate 2 from the substrate stage 1, and the like.

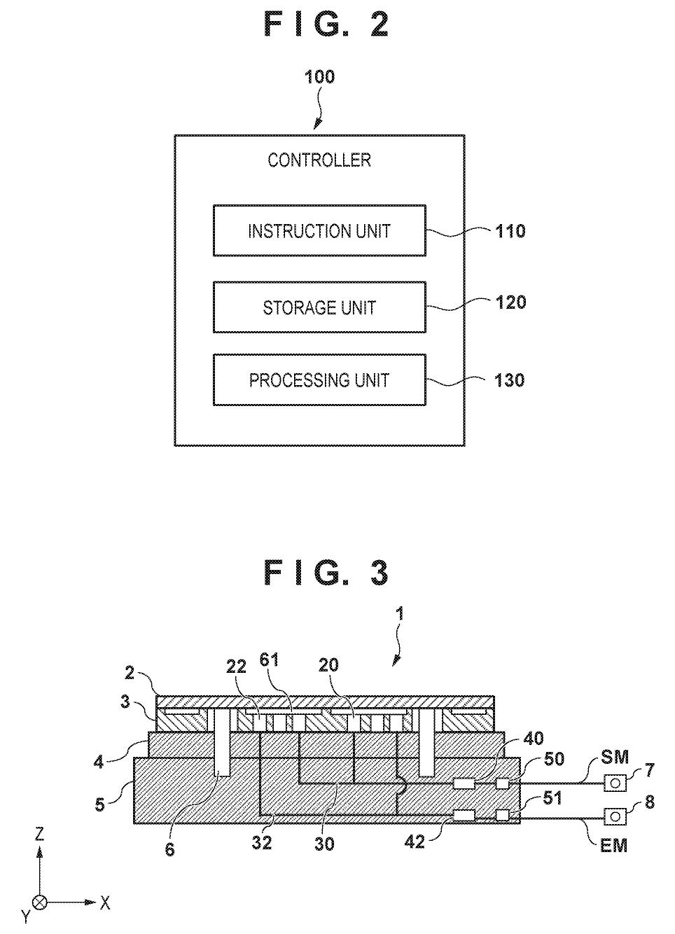

FIG. 2 shows the functional configuration of the controller 100. The controller 100 can include an instruction unit 110, a storage unit 120, and a processing unit 130. The instruction unit 110 instructs the control amounts to respective drivers including the fine moving stage 4. The storage unit 120 stores various data and programs related to exposure control. The processing unit 130 executes various processes related to exposure control. For example, the processing unit 130 calculates the drive target positions of the substrate stage 1 and the original stage 204. Furthermore, the processing unit 130 executes an exposure sequence and a substrate supply and recovery sequence in accordance with the control program stored in the storage unit 120.

With reference FIG. 3, a method of vacuum-sucking and holding the substrate 2 by the substrate chuck 3, and a method of supplying a gas to the space between the substrate 2 and the substrate chuck 3, will be explained. FIG. 3 is a schematic view showing an example of the configuration of the substrate stage 1. Note that the space between the substrate 2 and the substrate chuck 3 will sometimes be called a space 61 hereinafter. As shown in FIG. 3, the substrate stage 1 includes an exhaust mechanism EM used when holding the substrate 2 by the substrate chuck 3 and includes a supply mechanism SM used when canceling the holding of the substrate 2 by the substrate chuck 3.

The exhaust mechanism EM is a mechanism configured to exhaust a gas from the space 61 (first space) serving as the space between the substrate 2 and the substrate chuck 3. The exhaust mechanism EM includes a flow path (pipe) 32 (third flow path), a solenoid valve 42 (second valve), and a regulator 51. The supply mechanism SM is a mechanism configured to supply a gas to the space 61. The supply mechanism SM includes a flow path (pipe) 30 (first flow path), a solenoid valve 40 (first valve), and a regulator 50.

The substrate stage 1 vacuum-sucks and holds the substrate 2 by the substrate chuck 3 by exhausting the gas from the space 61 (decompression space) serving as the space between the substrate 2 and the substrate chuck 3 and reducing the pressure by the exhaust mechanism EM. The flow paths 30 and 32 are connected to the substrate chuck 3. The substrate chuck 3 is vacuum-sucked and held on the fine moving stage 4. The fine moving stage 4 is placed on the coarse moving stage 5. In this embodiment, the solenoid valves 40 and 42 and the regulators 50 and 51 are assembled in the coarse moving stage 5.

The flow path 30 connects, via the solenoid valve 40 provided on the flow path 30, the space 61 and a positive-pressure tank 7 serving as a positive-pressure source (gas supply source) that generates a positive pressure. The positive-pressure tank 7 is provided outside the coarse moving stage 5 and constituted as, for example, a plant facility. The solenoid valve 40 is interposed between the positive-pressure tank 7 and the substrate chuck 3. The flow path 32 connects, via the solenoid valve 42 provided on the flow path 32, the space 61 serving as the space between the substrate 2 and the substrate chuck 3, and a vacuum pump 8 that generates a negative pressure.

The regulator 51 is interposed between the vacuum pump 8 and the substrate chuck 3, specifically, between the vacuum pump 8 and the solenoid valve 42, and can regulate the pressure of the space 61 to a desired vacuum pressure. To supply the pressure regulated by the regulator 51 to the substrate chuck 3, the solenoid valve 42 is arranged on the side of the substrate chuck 3 with respect to the regulator 51. Under the control of the controller 100, the solenoid valve 42 is turned on (that is, the solenoid valve 42 is opened) to regulate the pressure of the space 61 by the vacuum pump 8. Also, under the control of the controller 100, the solenoid valve 42 is turned off (that is, the solenoid valve 42 is closed) to cancel the regulation of the pressure of the space 61 by the vacuum pump 8.

The regulator 50 is interposed between the positive-pressure tank 7 and the substrate chuck 3, specifically, between the positive-pressure tank 7 and the solenoid valve 40, and can regulate the pressure of the gas supplied from the positive-pressure tank 7 to a desired pressure. Regulating the pressure of the gas supplied from the positive-pressure tank 7 also means regulating the flow rate of the gas supplied from the positive-pressure tank 7. To supply the pressure regulated by the regulator 50 to the substrate chuck 3, the solenoid valve 40 is arranged on the side of the substrate chuck 3 with respect to the regulator 50. Under the control of the controller 100, the solenoid valve 40 is turned on (that is, the solenoid valve 40 is opened) to regulate the pressure of the space 61 by the positive-pressure tank 7. Also, under the control of the controller 100, the solenoid valve 40 is turned off (that is, the solenoid valve 40 is closed) to cancel the regulation of the pressure of the space 61 by the positive-pressure tank 7.

The solenoid valves 40 and 42 may be replaced with servo valves capable of freely setting the opening/closing degree, proportional solenoid valves controllable in proportion to the current, or the like.

When holding the substrate 2 by the substrate chuck 3, the solenoid valve 42 is turned on to depressurize the space 61 by the vacuum pump 8 and vacuum-suck the substrate 2 by the substrate chuck 3.

When canceling the holding of the substrate 2 by the substrate chuck 3, the solenoid valve 42 is turned off and the solenoid valve 40 is turned on to supply the gas from the stage space and the positive-pressure tank 7 to the space 61.

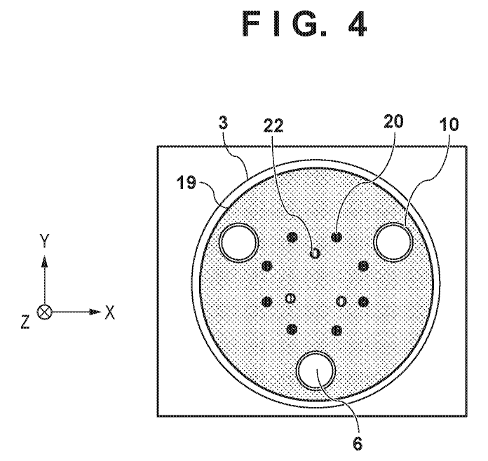

FIG. 4 is a plan view of the substrate chuck 3 when viewed from the +Z direction. In FIG. 4, an annular sealing portion 19 is provided on the substrate chuck 3 along the outer periphery of the substrate chuck 3, but the sealing portion 19 provided on the substrate chuck 3 is not always necessary. The number and layout of sealing portions 19 provided on the substrate chuck 3 are not limited to any specific number and any specific layout.

A plurality of projections (not shown) called chuck pins are provided on the substrate chuck 3, and the chuck pins define a holding surface on which the substrate 2 is held. A supply hole 20 continuous with the flow path 30 and an exhaust hole 22 continuous with the flow path 32 are formed in the holding surface of the substrate chuck 3.

In the example shown in FIG. 4, eight supply holes 20 are provided at equal intervals on the same circle (concentrically) on which distances from the center of the substrate chuck 3 are equal. However, the present disclosure is not limited to this. Also, three exhaust holes 22 are provided on the same circle (concentrically) on which distances from the center of the substrate chuck 3 are equal. However, the present disclosure is not limited to this.

As shown in FIG. 4, through holes 10 are provided in the substrate chuck 3 and the fine moving stage 4 so that the pin members 6 pass through the through holes 10. The fine moving stage 4 can be driven in the Z direction without interfering with the pin members 6.

The operation of vacuum-sucking and holding the substrate 2 by the substrate chuck 3 is performed by exhausting, by the exhaust mechanism EM via the exhaust holes 22, the gas in the space 61 serving as the space between the substrate 2 and the substrate chuck 3. In this manner, the gaps between the substrate 2 and the small chuck pins are evacuated via the exhaust holes 22, and the substrate chuck 3 can vacuum-suck and hold the substrate 2 by a uniform force. In this embodiment, the presence of the sealing portion 19 between the substrate 2 and the substrate chuck 3 can prevent the inflow of the gas (air) from the stage space and enable vacuum-sucking the substrate 2.

The operation of canceling the holding of the substrate 2 by the substrate chuck 3 is performed by supplying, by the supply mechanism SM (supplier) via the supply holes 20, the gas from the positive-pressure tank 7 to the space 61.

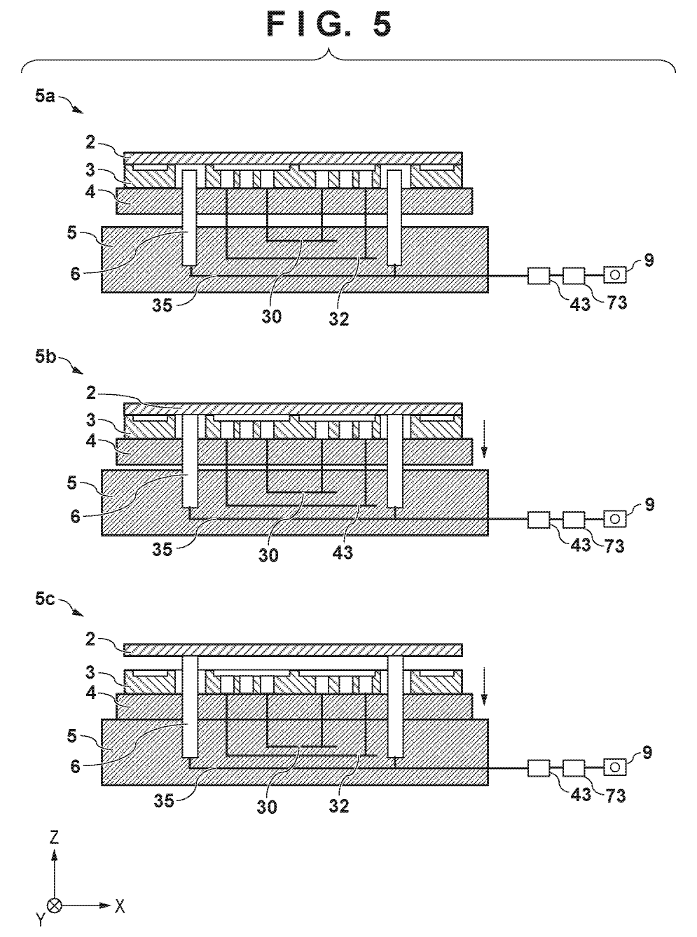

Next, a method of transferring the substrate 2 from the substrate chuck 3 to the pin members 6 will be explained with reference to FIG. 5. FIG. 5 shows sectional views of the substrate stage 1 in states 5a, 5b, and 5c, respectively.

The pin member 6 is a member that protrudes from the through hole 10 formed in the substrate chuck 3, thereby supporting the substrate 2. The fine moving stage 4 can include a driver that drives the fine moving stage 4 in the Z direction along the pin members 6 (in the longitudinal direction thereof) so as to change the height of the fine moving stage 4. Note that the driver of the fine moving stage 4 can cause the fine moving stage 4 to be driven while tilted in the Z direction in accordance with the positions of the three pin members 6 in the Z direction. As described above, the pin members 6 are fixed to the coarse moving stage 5 drivable in the X and Y directions. The position of the pin member 6 is measured by a measurement device including, for example, an interferometer, a capacitance sensor, an encoder, and the like.

The pin members 6 are connected to a vacuum pump 9 via a flow path 35. A regulator 73 and a solenoid valve 43 are interposed between the vacuum pump 9 and the pin members 6. To supply a pressure regulated by the regulator 73 to the pin members 6, the solenoid valve 43 is arranged on the side of the pin members 6 with respect to the regulator 51. Under the control of the controller 100, the solenoid valve 43 is turned on (that is, the solenoid valve 43 is opened) to regulate the pressure of the space between the substrate 2 and the substrate chuck 3 by the vacuum pump 9 via the pin members 6. Also, under the control of the controller 100, the solenoid valve 43 is turned off (that is, the solenoid valve 43 is closed) to cancel the regulation of the pressure of the space between the substrate 2 and the substrate chuck 3 by the vacuum pump 9 via the pin members 6. In this embodiment, the solenoid valve 43 and the regulator 73 are provided outside the coarse moving stage 5, that is, in the stage space, but may be assembled in the coarse moving stage 5. The vacuum pump 9 is constituted as, for example, a plant facility.

In the state 5a shown in FIG. 5, the fine moving stage 4 is positioned in the +Z direction, and the substrate chuck 3 vacuum-chucks the substrate 2. In the state 5b shown in FIG. 5, as indicated by an arrow, the fine moving stage 4 is driven in the -Z direction to bring the pin members 6 and the substrate 2 into contact with each other. At this time, the fine moving stage 4 may stop the driving. After the pin members 6 and the substrate 2 contact each other, the holding of the substrate 2 by the substrate chuck 3 is canceled. In addition, the solenoid valve 43 is turned on to vacuum-suck and hold the substrate 2 by the pin members 6. In the state in which the pin members 6 hold the substrate 2, the fine moving stage 4 is further driven in the -Z direction to transfer the substrate 2 from the substrate chuck 3 to the pin members 6, as illustrated in the state 5c shown in FIG. 5.

Here, the method of driving the fine moving stage 4 to transfer the substrate 2 from the substrate chuck 3 to the pin members 6 has been explained. However, the present disclosure is not limited to this, and it is only necessary to change the relative positions of the substrate chuck 3 and pin members 6 in the Z direction. For example, a driver may drive the whole pin members 6 or their distal ends in the Z direction to transfer the substrate 2 from the substrate chuck 3 to the pin members 6. Changing the relative positions of the substrate chuck 3 and pin members 6 is synonymous with relatively driving the substrate chuck 3 and the pin members 6.

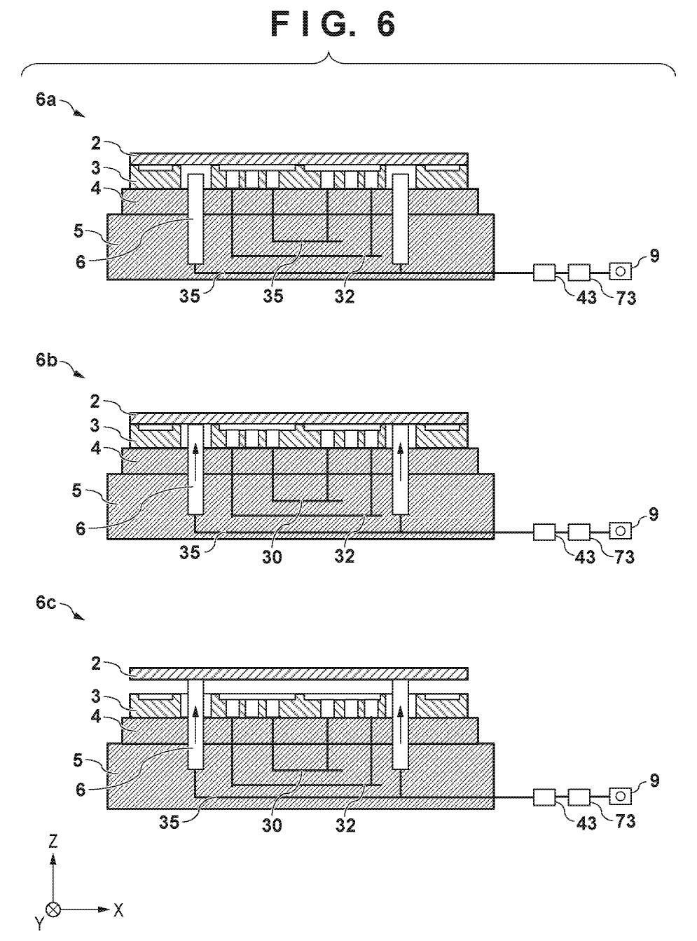

A method of transferring the substrate 2 from the substrate chuck 3 to the pin members 6 by driving the whole pin members 6 in the Z direction will be explained with reference to FIG. 6. FIG. 6 shows sectional views of the substrate stage 1 in states 6a, 6b, and 6c, respectively. A driver that drives the pin members 6 may be incorporated in the pin members 6, or provided outside the pin members 6 and connected to the pin members 6. Note that, as described above, the distal ends of the pin members 6 may be driven (extended) in the Z direction to transfer the substrate 2 from the substrate chuck 3 to the pin members 6, instead of driving the whole pin members 6.

In the state 6a shown in FIG. 6, the pin members 6 are positioned in the -Z direction and do not contact the substrate 2. In this state, the substrate chuck 3 holds the substrate 2. In the state 6b shown in FIG. 6, as indicated by an arrow, driving the pin member 6 in the +Z direction causes the pin member 6 to approach and come into contact with the substrate 2. After the pin members 6 and the substrate 2 contact each other, the driving of the pin members 6 is stopped, and the holding of the substrate 2 by the substrate chuck 3 is canceled. Then, the solenoid valve 43 is turned on to vacuum-suck the substrate 2 by the pin members 6. In the state in which the pin members 6 hold the substrate 2, the pin members 6 are further driven in the +Z direction to transfer the substrate 2 from the substrate chuck 3 to the pin members 6, as illustrated in the state 6c shown in FIG. 6.

The substrate stage 1 (stage apparatus) can include the driver that drives the fine moving stage 4 shown in FIG. 5, the driver that drives the pin member 6 shown in FIG. 6, or both of them. These drivers function as a driver (relative driver) that moves at least one of the substrate chuck 3 and the pin members 6 in a direction in which the pin members 6 rise and lower through the through holes 10 relative to the height of the holding surface of the substrate chuck 3.

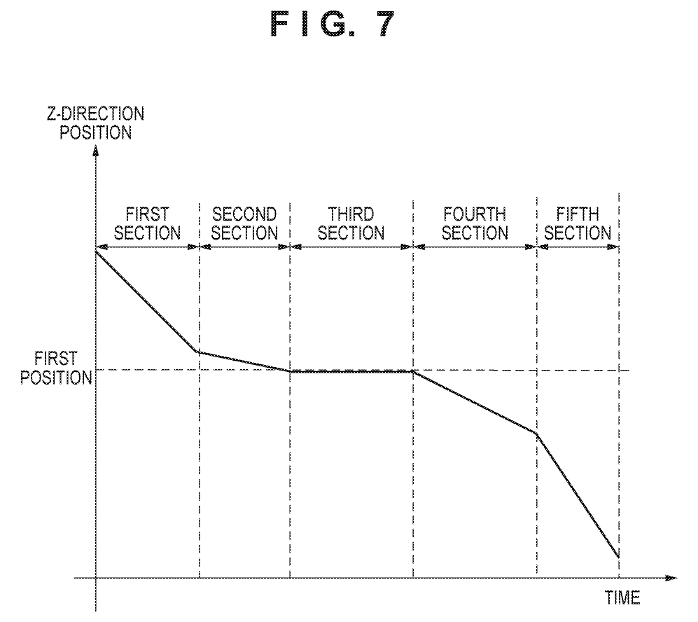

The controller 100 controls the driver, the supply mechanism SM, and the exhaust mechanism EM by following a control sequence based on a control profile (drive profile) defining the time-series transition of the target position of the fine moving stage 4 serving as the driver. FIG. 7 shows an example of the control profile (drive profile) defining the time-series transition of the target position of the fine moving stage 4 serving as the driver. The target position of the driver indicates the target position concerning the relative position between the substrate chuck 3 and the pin member 6. FIG. 7 shows the relationship between time and the Z-direction position of the fine moving stage 4 in the operation of transferring the substrate 2 from the substrate chuck 3 to the pin members 6. Note that the change amount of the Z-direction position of the fine moving stage 4 is synonymous with the change amount of the Z-direction position of the substrate chuck 3.

In the first section, the instruction unit 110 instructs the fine moving stage 4 to set the first position stored in the storage unit 120 as the target position to move the fine moving stage 4 at high speed in the -Z direction. When driving the fine moving stage 4 in the -Z direction, the first position is set to be the same position as the Z-direction position of the fine moving stage 4 where the pin members 6 come into contact with the substrate 2, or the position on the +Z direction side of this position. Here, the example is shown in which the fine moving stage 4 moves in the -Z direction as in FIG. 5. However, since the case where the pin members 6 are moved in the +Z direction as in FIG. 6 is different from this example only in the moving direction, FIG. 7 is applicable to the case by exchanging the -Z direction and the +Z direction in FIG. 7. The drawings and explanations described below can also be applied to the case where the pin members 6 are moved in the +Z direction by exchanging the -Z direction and the +Z direction. Furthermore, in a form where both the fine moving stage 4 and the pin members 6 are driven, moving the fine moving stage 4 in the Z direction in the explanation of FIG. 7 and the drawings described below may be replaced with an explanation of relatively moving the fine moving stage 4 and the pin members 6.

In the second section, the controller 100 moves the fine moving stage 4 at low speed in the -Z direction, and monitors the drive current value in the driving of the fine moving stage 4. By monitoring the drive current value while moving the fine moving stage 4 in the -Z direction, the controller 100 can detect the drive current value which changes when the pin members 6 come into contact with the substrate 2, thereby detecting that the pin members 6 have come into contact with the substrate 2. The reason why the fine moving stage 4 is driven at low speed in the second section is that the substrate 2 and the pin members 6 may be damaged if the substrate 2 is brought into contact with the pin members 6 at high speed. If it is detected that the pin members 6 have come into contact with the substrate 2 by monitoring the drive current value, the controller 100 stops moving the fine moving stage 4 in the -Z direction, and ends the second section. Note that the controller 100 may update the value of the first position stored in the storage unit 120 with the value of the Z-direction position of the fine moving stage 4 at the time of detection of the contact between the pin members 6 and the substrate 2 in the second section. By updating the first position in this manner, the time required for the second section can be reduced.

If the coordinates of the fine moving stage 4 when the substrate 2 comes into contact with the pin members 6 are the same as those of the first position, the substrate 2 and the pin members 6 are in contact with each other when the fine moving stage 4 has moved at the first position. In this case, at the same time as the start of the second section, it is detected that the substrate 2 and the pin members 6 have come into contact from the drive current value. Hence, the fine moving stage 4 is not moved at low speed in the second section, and the operation transitions to the third section. Note that if it is known that the coordinates of the fine moving stage 4 when the substrate 2 and the pin members 6 come into contact are the same as those of the first position, the second section may be omitted and the operation may transition to the third section after the first section. If the substrate 2 and the pin members 6 are in contact, both may wear or be damaged in the third section due to vibration of the apparatus or the like. To prevent this, the operation may transition to the third section after moving the pin members 6 and the substrate 2 only by a small distance in the separation direction within the range where the substrate 2 can be chucked by sucking the gas by the pin members 6. The separation distance is, for example, 10 to 70 μm. Also, by updating the first position at a position where the substrate 2 and the pin members 6 are separated by a small distance, and defining the position where the substrate 2 and the pin members 6 are separated by the small distance as the position where the first section ends, the second section may be omitted.

In the third section, the controller 100 stops suction of the gas between the substrate 2 and the substrate chuck 3, and in parallel therewith, supplies a gas between the substrate 2 and the substrate chuck 3. In the third section, the pin members 6 also start to suck the gas between the substrate 2 and the pin members 6.

In the fourth section, the controller 100 moves the fine moving stage 4 at low speed in the -Z direction, thereby separating the substrate 2 and the substrate chuck 3 by a small distance.

In the fifth section, the fine moving stage 4 is moved at high speed in the -Z direction to the final position in the Z direction.

The above-described control profile can include:

the first period (corresponding to the first section and the second section in FIG. 7) during which, from the state in which the substrate 2 is placed on the substrate chuck 3, the driver drives so as to make the pin members 6 protrude from the through holes 10 and approach the substrate 2

the second period (corresponding to the third section in FIG. 7) during which, after the first period, the driver stops in a state in which the substrate 2 and the pin members 6 are close (for example, in contact with each other)

the third period (corresponding to the fourth section and the fifth section in FIG. 7) during which, after the second period, the driver drives so as to separate the substrate 2 and the substrate chuck 3

In the example shown in FIG. 7, the separation process between the substrate 2 and the substrate chuck 3 is divided into two sections of the fourth section and the fifth section. However, the present disclosure is not limited to this, and the separation process may be divided into three or more sections. For example, the separation process between the substrate 2 and the substrate chuck 3 may be divided into three sections of the fourth to sixth sections, and the fine moving stage 4 may be moved at low speed in the fourth section, at middle speed in the fifth section, and at high speed in the sixth section. In addition, in this embodiment, the speed is changed at the instant of transition from the previous section to the next section. However, the present disclosure is not limited to this, and the speed may be gradually changed between the previous section and the next section.

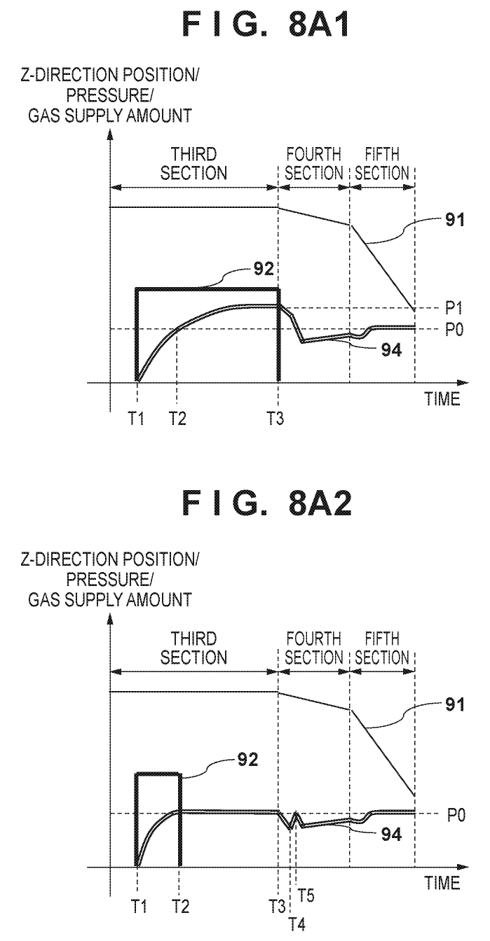

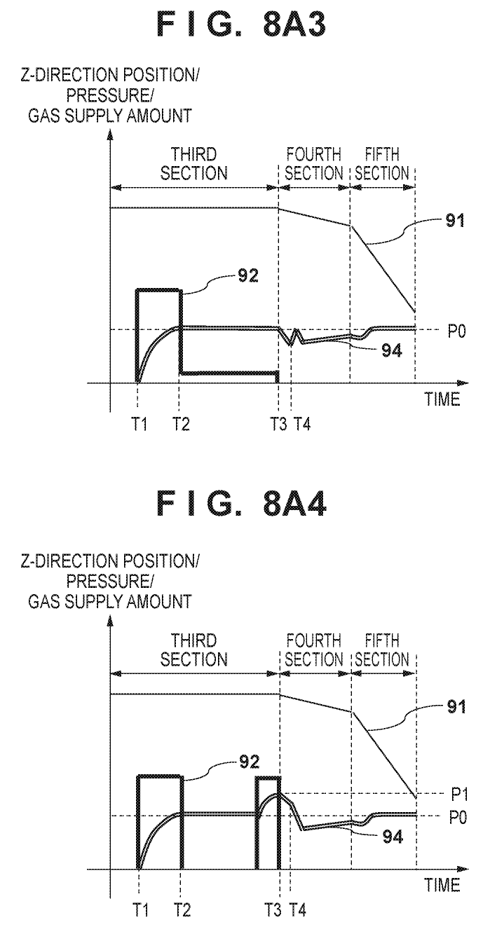

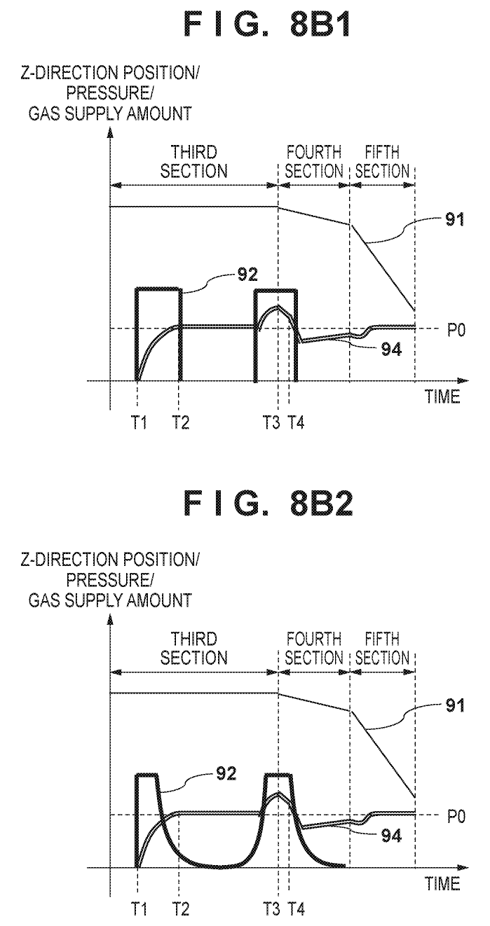

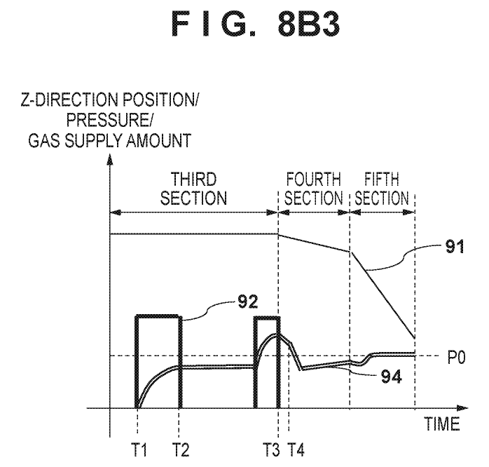

If the gas supply is insufficient in the third section, the chucking force remains between the substrate 2 and the substrate chuck 3. In this state, if the substrate 2 and the substrate chuck 3 are separated in the fourth section, the substrate chuck 3 wears. To the contrary, if the gas supply is excessive in the third section, a problem occurs that the substrate 2 laterally shifts with respect to the substrate chuck 3. With reference to FIGS. 8A1 to 8A4,8B1 to 8B3 and 9, a method of canceling the chucking between the substrate 2 and the substrate chuck 3 while suppressing the lateral shift of the substrate 2 with respect to the substrate chuck 3 will be described below. FIGS. 8A1 to 8A4 show some examples of the control profile from the third section to the fifth section. In FIGS. 8A1 to 8A4, a solid line 91 represents the time-series transition of the Z-direction position of the fine moving stage 4, a solid line 92 represents the time-series transition of the gas supply amount from the supply mechanism SM, and a double line 94 represents the time-series transition of the pressure of the space 61 between the substrate 2 and the substrate chuck 3. P0 represents atmospheric pressure. In FIG. 8A1 , in the third section, after the gas supply is started at time T1, the pressure 94 of the space 61 rises and reaches the atmospheric pressure P0 at time T2. As the gas continues to be supplied thereafter, the pressure 94 of the space 61 further rises up to a pressure P1 higher than the atmospheric pressure P0.

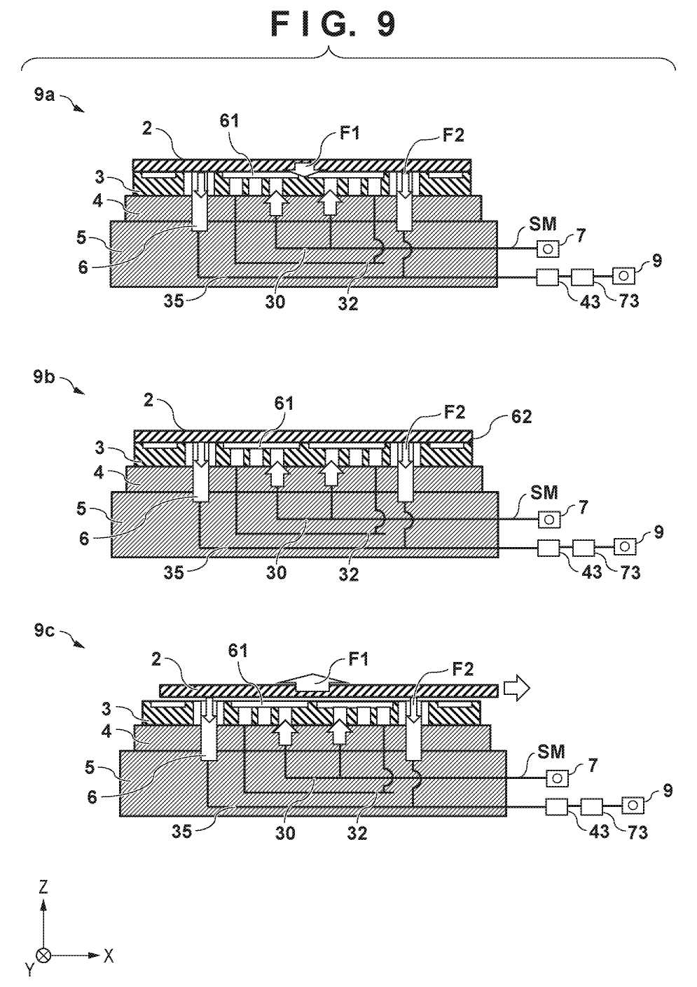

In FIG. 9, a state 9a shows the state of the substrate stage 1 at time T1 in FIG. 8A1 . Immediately after T1, a pressurized gas is supplied to the space 61 by the supply mechanism SM but the space 61 is still under a negative pressure. Accordingly, a downward chucking force F1 in the Z direction acts on the substrate 2. At the same time, a chucking force F2 generated by exhaustion from the pin members 6 also acts on the substrate 2. Since the both forces acting on the substrate 2 are downward forces in the Z direction, the substrate 2 is held by the substrate chuck 3 and the pin members 6. A state 9b shows the state of the substrate stage 1 at time T2 in FIG. 8A1 . At this point of time, the pressure of the space 61 is equal to atmospheric pressure. Accordingly, no force is applied to the substrate 2. On the other hand, the chucking force F2 generated by the pin members 6 acts on the substrate 2. Hence, the substrate 2 is held by the pin members 6. A state 9c shows the state of the substrate stage 1 at time T3 in FIG. 8A1 . At this point of time, the pressure of the space 61 reaches the pressure P1 which is higher than atmospheric pressure. Accordingly, the upward force F1 in the Z direction acts on the substrate 2. In addition, the chucking force F2 generated by the pin members 6 acts on the substrate 2. At this time, if F1 is larger than F2, the pin members 6 cannot chuck and hold the substrate 2, and the substrate 2 laterally shifts as shown in the state 9c.

To prevent this, in the third section, it is necessary to adjust the gas supply amount by the supply mechanism SM so as to make the force F1 generated by the pressure of the space 61 smaller than the chucking force F2 generated by the pin members 6. To achieve this, for example, as shown in FIG. 8A2 , at time T2 when the pressure 94 of the space 61 becomes equal to atmospheric pressure, the gas supply amount 92 may be set to zero. In this case, the pressure of the space 61 does not become higher than atmospheric pressure, so F1 does not exceed F2, thereby making it difficult for the substrate 2 to laterally shift. The pressure of the space 61 may exceed atmospheric pressure within the range where the substrate chuck 3 can hold the substrate 2, for example, within the range where F1 does not exceed F2.

From time T2 in FIG. 8A2 , chucking by the negative pressure does not occur between the substrate 2 and the substrate chuck 3. Therefore, a gap connecting to the surrounding of the substrate chuck 3 may be present in the space 61. In that case, even if the gas supply from the supply mechanism SM is continued from T2, the gas leaks through the gap, making it difficult for the space 61 to reach atmospheric pressure or higher. Accordingly, it is not necessary to completely set the gas supply amount 92 to zero at time T2. As shown in FIG. 8A3 , from time T2, a weak gas supply may be continued within the range where the substrate chuck 3 can hold the substrate 2. The gas supply amount may be adjusted by changing the supply pressure.

As described above, in this embodiment, the controller 100 starts the supply (first supply) of gas by the supply mechanism SM (supplier) in the third section (second period), and terminates the first supply by reducing the supply amount of gas from the supply mechanism SM before the third section ends. Here, reducing the supply amount of gas from the supply mechanism SM can include stopping the gas supply as shown from T2 in FIG. 8A2. In this manner, the control method of the substrate stage 1 according to this embodiment includes a step of controlling the driver and the supplier based on the control profile. This step includes a step of starting the first supply of gas by the supplier in the second period, and a step of terminating the first supply by reducing the supply amount of gas from the supplier before the second period ends.

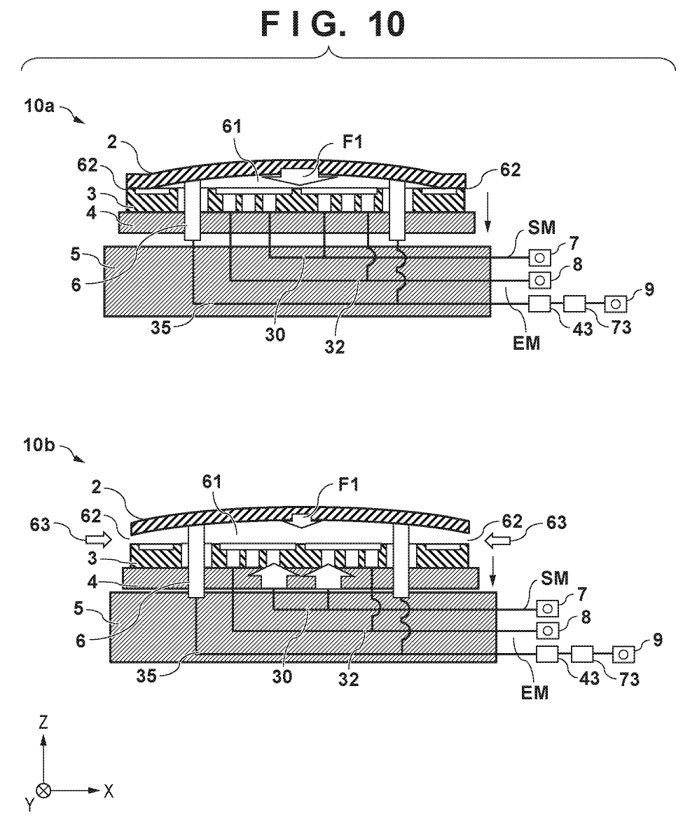

At time T4 in the fourth section shown in FIG. 8A2 , the pressure of the space 61 temporarily drops below atmospheric pressure and then returns to atmospheric pressure again. The reason for this will be explained with reference to FIG. 8A2 and FIG. 10. A state 10a in FIG. 10 shows an example of the state of the substrate stage 1 at a certain time between time T3 and time T4 in FIG. 8A2 . By driving the fine moving stage 4 in the -Z direction, the pin members 6 push the substrate 2 from below to separate the substrate 2 from the substrate chuck 3. However, the end portion (outer peripheral portion) of the substrate 2 adheres to the substrate chuck 3 so that the space 61 is isolated from the surrounding space. Although the space 61 is expanded, no gas is supplied from the surrounding, and this can cause a temporary drop of the pressure of the space 61. A state 10b shows an example of the state of the substrate stage 1 at a certain time between time T4 and time T5 in FIG. 8A2 . By driving the fine moving stage 4 in the -Z direction, a gap 62 is formed between the end portion of the substrate 2 and the substrate chuck 3, and a gas 63 from the surrounding flows therein. This can cause the negative pressure of the space 61 to be canceled and return to atmospheric pressure.

Thus, after the pressure of the space 61 becomes equal to atmospheric pressure in the third section, and the chucking force between the substrate 2 and the substrate chuck 3 is eliminated, a negative pressure can be generated again in the early stage of the fourth section when the fine moving stage 4 is moved in the -Z direction. However, if the substrate 2 is separated while the negative pressure exists between the substrate 2 and the substrate chuck 3, the chuck wears. To prevent this, as shown in FIGS. 8A4, in the third section (second period), after the above-described first supply is terminated, the controller 100 may start the resupply (second supply) of gas by the supply mechanism SM. This can set the pressure of the space 61 to be higher than atmospheric pressure at the end of the third section, thereby canceling generation of the negative pressure in the early stage of the fourth section. In this case, the gas supply amount and the supply pressure may not be the same before and after the resupply. The gas supply amount in the second supply may be different from the gas supply amount in the first supply.

In the example shown in FIG. 8A4 , the controller 100 starts the second supply in the middle of the third section (second period), and terminates the second supply before transition to the fourth section (third period). However, if the surface flatness of each of the substrate 2 and the substrate chuck 3 is high, the substrate 2 and the substrate chuck 3 may adhere to each other due to ringing. In that case, even if the pressure of the space 61 is higher than atmospheric pressure, the substrate 2 and the substrate chuck 3 can remain adhered at the start of the fourth section. To prevent this, as shown in FIG. 8B1, the controller 100 may start the second supply in the middle of the third section, transition to the fourth section (third period) without stopping the gas, and terminate the second supply after transition to the fourth section (third period). With this, the pressure of the space 61 rises, so that the ease of separation between the substrate 2 and the substrate chuck 3 adhered by ringing can be improved.

When the pressure of the space 61 is equal to or higher than atmospheric pressure, the chucking force between the substrate 2 and the substrate chuck 3 is weak, so that the lateral shift of the substrate 2 easily occurs. Therefore, if the gas supply amount or the supply pressure is abruptly changed, the pressure of the space 61 fluctuates, and this may induce, for example, vibrations of the substrate 2, the substrate chuck 3, and the pin members 6. Such vibrations can cause the lateral shift of the substrate 2 and the wears of the pin member 6 and the substrate chuck 3. To prevent this, as shown in FIG. 8B2 , when starting and stopping the gas supply in each of the first supply and the second supply, the controller 100 may gradually change the gas supply amount in accordance with the elapse of time.

When the pressure of the space 61 is equal to or higher than atmospheric pressure, the lateral shift of the substrate 2 easily occurs. To prevent this, as shown in FIG. 8B3 , in the third section, the controller 100 terminates the first supply by reducing or stopping the gas supply amount from the supply mechanism SM when the pressure of the space 61 is lower than atmospheric pressure, and then starts the second supply prior to the fourth section. With this, it is possible to start -Z driving after raising the pressure of the space 61 above atmospheric pressure and eliminating the chucking force between the substrate 2 and the substrate chuck 3 before transition to the fourth section.

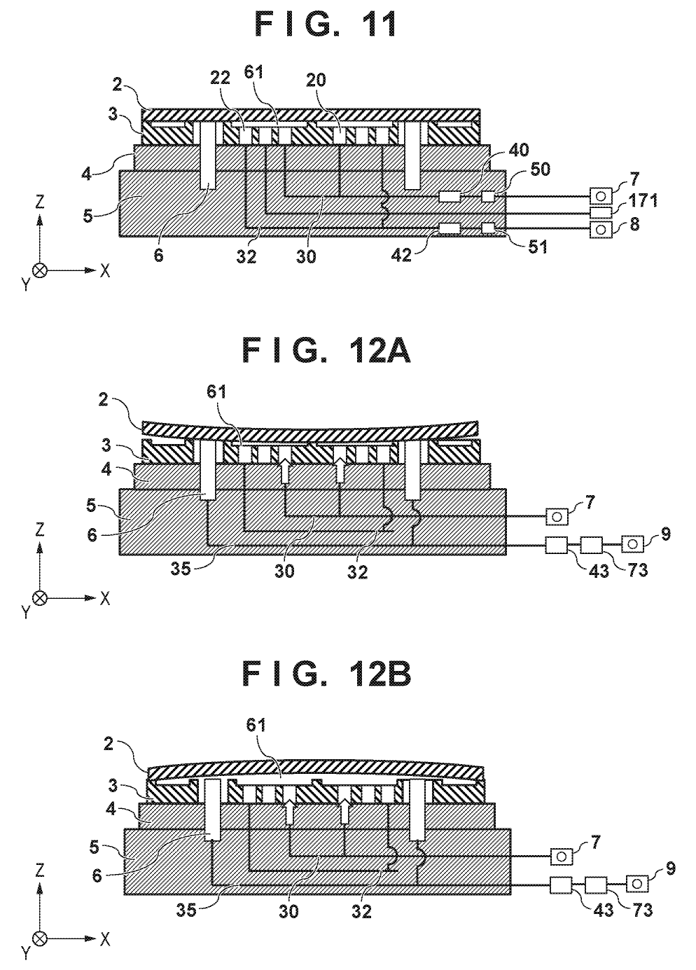

The controller 100 can decide the timing for stopping the first supply based on the pressure of the space 61. For example, in the third section, the timing when the space 61 between the substrate 2 and the substrate chuck 3 reaches atmospheric pressure may be detected by a pressure sensor, and the gas supply from the supply mechanism SM may be stopped (or the supply pressure may be reduced) at the detected timing. In a case of setting the pressure of the space 61 higher than atmospheric pressure, the timing of stopping the gas supply may be set later than the timing when the pressure sensor detects that the space 61 reaches atmospheric pressure. In a case of setting the pressure of the space 61 lower than atmospheric pressure, the timing of stopping the gas supply may be set earlier than the timing when the pressure sensor detects that the space 61 reaches atmospheric pressure. FIG. 11 shows an example of the configuration in which a pressure sensor 171 is installed in a system communicating with the space 61 to measure the pressure of the space 61 in the substrate stage 1. In FIG. 11, the pressure sensor 171 is provided outside the substrate stage 1. However, the present disclosure is not limited to this, and the pressure sensor 171 may be provided inside the substrate stage 1. Pressure data may be collected for each processing of the substrate 2, and the timing of stopping the gas supply from the supply mechanism SM or lowering the supply pressure may be decided based on the collected past data.

The controller 100 can decide the timing of stopping the first supply based on the volume of the space 61. In the third section, the timing when the space 61 between the substrate 2 and the substrate chuck 3 reaches atmospheric pressure can be a timing when the volume of the space 61 matches the gas supply amount from the supply mechanism SM. Hence, at this timing, the gas supply may be stopped or the supply pressure may be lowered. In a case of setting the pressure of the space 61 higher than atmospheric pressure, the timing of stopping the supply or lowering the supply pressure may be set later than the timing when the volume of the space 61 matches the gas supply amount from the supply mechanism SM. In a case of setting the pressure of the space 61 lower than atmospheric pressure, the timing of stopping the supply or lowering the supply pressure may be set earlier than the timing when the volume of the space 61 matches the gas supply amount from the supply mechanism SM.

The controller 100 can decide the timing of stopping the first supply based on the warpage amount (deformation amount) of the substrate 2. When the substrate 2 is downward convex as shown in FIG. 12A, the volume of the space 61 can be smaller than when the substrate 2 is flat. Accordingly, the timing of stopping the gas supply from the supply mechanism SM may be set early. To the contrary, when the substrate 2 is upward convex as shown in FIG. 12B, the volume of the space 61 can be larger than when the substrate 2 is flat. Accordingly, the timing of stopping the gas supply from the supply mechanism SM or lowering the supply pressure may be set late.

The controller 100 can decide the timing of stopping the first supply based on the characteristic of the substrate 2, for example, the material of the substrate 2. The characteristic of the substrate 2 includes at least one of the warpage amount, the roughness of the surface (back surface) of the substrate 2 which comes into contact with the holding surface of the substrate chuck 3, the kind of film formation performed on the substrate 2, the material of the substrate 2, and the thickness of the substrate 2. For example, when the substrate 2 is warped, stress acts in the direction of separating the substrate 2 from the substrate chuck 3 and the degree of adhesion decreases. Thus, the adhesion force becomes weaker than when the substrate 2 is flat. When the back surface of the substrate 2 is not rough, the substrate 2 and the substrate chuck 3 adhere firmly to each other so that the adhesion force is strong. When the back surface of the substrate 2 is rough, the substrate 2 and the substrate chuck 3 do not adhere tightly to each other so that the adhesion force is weak. When film formation is performed on the back surface of the substrate, the kind of film formation can influence the adhesion force. Furthermore, the weight of the substrate 2 changes depending on the material and thickness of the substrate 2. The heavier the substrate 2, the stronger the adhesion force since the substrate 2 and the substrate chuck 3 adhere firmly to each other. Based on these characteristics, if the adhesion force is weak, the timing of stopping the gas supply or lowering the supply pressure may be set early. To the contrary, if the adhesion force is strong, the timing of stopping the gas supply or lowering the supply pressure may be set late. Adhesion force data may be collected for each processing of the substrate 2, and the timing of stopping the gas supply from the supply mechanism SM or lowering the supply pressure may be decided based on the collected past data.

The controller 100 can decide the timing of stopping the first supply based on the characteristic of the substrate chuck 3 such as the material. The characteristic of the substrate chuck 3 is based on at least one of the height uniformity of the chuck pin (the flatness of the holding surface), the surface coating of the chuck pin (the surface roughness of the holding surface), the thickness of the chuck pin, the material thereof, and the like. For example, the higher the height uniformity of the chuck pin, the more firmly the substrate 2 and the substrate chuck 3 adhere to each other, resulting in a strong adhesion force. The thicker the pin of the substrate chuck 3, the larger the contact area with the substrate, resulting in a strong adhesion force. When the material of the pin of the substrate chuck 3 contains, for example, a substance with fine particles, the substrate 2 and the substrate chuck 3 adhere firmly to each other, resulting in a strong adhesion force. Based on these characteristics, if the adhesion force is weak, the timing of stopping the gas supply or lowering the supply pressure may be set early. To the contrary, if the adhesion force is strong, the timing of stopping the gas supply or lowering the supply pressure may be set late. Adhesion force data may be collected for each processing of the substrate 2, and the timing of stopping the gas supply from the supply mechanism SM or lowering the supply pressure may be decided based on the collected past data.

The controller 100 can decide the timing of stopping the first supply based on the driving force of the driver or the drive current value in the driver. The driving force refers to a force generated when the driver moves in the Z direction to separate the substrate 2 from the substrate chuck 3, for example, a force for relatively moving the fine moving stage 4 and the pin members 6. For example, the driving force in a state is measured in advance while there is no chucking force between the substrate 2 and the substrate chuck 3, and the obtained value is used as a reference value. If the driving force after the fourth section starts is larger than the reference value, this means that the chucking force between the substrate 2 and the substrate chuck 3 was not eliminated by the gas supply in the third section. In this case, the timing of stopping the gas supply in the third section may be set late in the next substrate processing. To the contrary, if the driving force after the fourth section starts is smaller than the reference value, this means that the pressure between the substrate 2 and the substrate chuck 3 became equal to or higher than atmospheric pressure due to the gas supply in the third section. In this case, the timing of stopping the gas supply in the third section may be set early. When using a method in which the driver generates the driving force by power, the drive current changes in accordance with the driving force. Therefore, the timing of stopping the gas supply or lowering the supply pressure may be decided based on the drive current value. Driving force data or drive current value data may be collected for each processing of the substrate 2, and the timing of stopping the gas supply from the supply mechanism SM or lowering the supply pressure may be decided based on the collected past data.

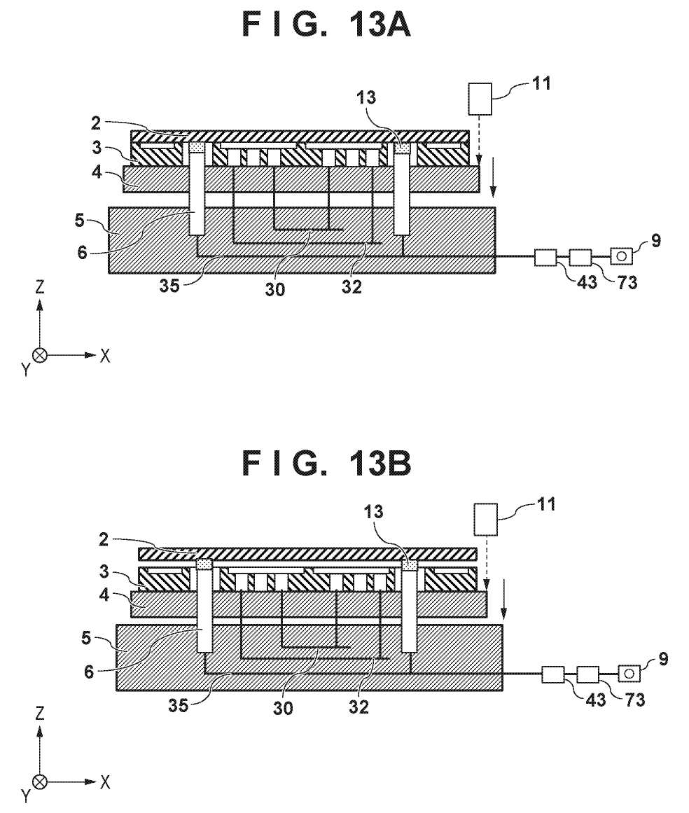

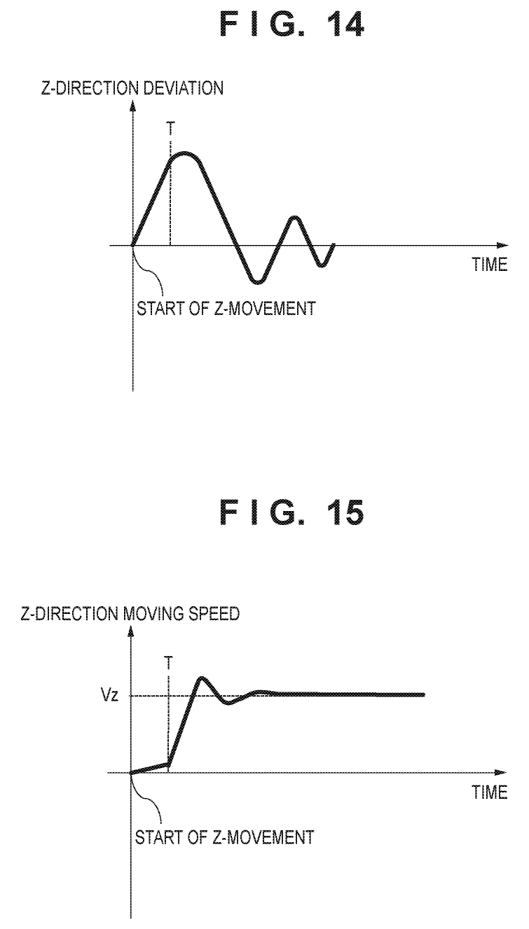

The controller 100 can decide the timing of stopping the first supply based on the Z deviation. The Z deviation indicates the difference (control deviation) between the target value and the actual measured value of the Z-direction position of the driver that operates when separating the substrate 2 from the substrate chuck 3. FIGS. 13A and 13B show an example in which a distance sensor 11 for measuring the Z-direction position of the fine moving stage 4 is installed in the substrate stage 1. The Z-direction position measurement point is not limited to the fine moving stage 4, and may be, for example, the substrate chuck 3. The distance sensor 11 may be an encoder. FIG. 14 shows an example of the temporal change of the Z deviation during a separation operation. The origin (the intersection of the ordinate and the abscissa) represents the point of time when the Z-driving for separating the substrate 2 from the substrate chuck 3 is started. If the initial state is one in which the substrate 2 and the substrate chuck 3 adhere to each other so that they are difficult to separate, the fine moving stage 4 cannot move to the target position instructed by the instruction unit 110. Hence, the target position and the actual position are different in the Z direction, and a Z deviation can be generated. Accordingly, the magnitude of the chucking force generated between the substrate 2 and the substrate chuck 3 can be determined from the maximum value or minimum value of the Z deviation. For example, if it is determined that the chucking force after the fourth section starts is larger than a threshold value, the timing of stopping the gas supply or lowering the supply pressure in the third section may be set late in the next substrate processing. To the contrary, if it is determined that the chucking force after the fourth section starts is equal to or smaller than the threshold value, the timing of stopping the gas supply or lowering the supply pressure in the third section may be set early. When using the method of separating the substrate 2 from the substrate chuck 3 by moving the pin members 6 in the +Z direction, the Z deviation may be measured from the Z-direction position of the substrate 2. In this case, the measurement position may be an arbitrary position on the substrate 2. Z-deviation data may be collected for each processing of the substrate 2, and the timing of stopping the gas supply from the supply mechanism SM or lowering the supply pressure may be decided based on the collected past data.

The controller 100 can decide the timing of stopping the first supply based on the moving speed of the driver. The moving speed of the driver refers to the relative moving speed in the Z direction (Z-direction moving speed) between the substrate chuck 3 and the substrate (pin member 6) by the driver when separating the substrate 2 from the substrate chuck 3. The Z-direction moving speed may be obtained by measuring the Z-direction position of the fine moving stage 4, like the distance sensor 11 shown in FIGS. 13A and 13B. The Z-direction moving speed may be obtained by measuring the Z- direction position of the substrate chuck 3 by using a sensor (not shown). The sensor may be an encoder. FIG. 15 shows an example of the Z-direction moving speed during a separation operation. In FIG. 15, Vz represents the target speed instructed by the instruction unit 110. The origin (the intersection of the ordinate and the abscissa) represents the point of time when the Z-driving for separating the substrate 2 from the substrate chuck 3 is started. If the initial state is one in which the substrate 2 and the substrate chuck 3 adhere to each other so that they are difficult to separate, the moving speed of the fine moving stage 4 can be lower than the target speed instructed by the instruction unit 110. Accordingly, the magnitude of the chucking force generated between the substrate 2 and the substrate chuck 3 can be determined from the difference between the target speed and the actual speed of the driver. If it is determined that the chucking force after the fourth section starts is large, the timing of stopping the gas supply or lowering the supply pressure in the third section may be set late in the next substrate processing. To the contrary, if it is determined that the chucking force after the fourth section starts is small, the timing of stopping the gas supply or lowering the supply pressure in the third section may be set early. When using the method of separating the substrate 2 from the substrate chuck 3 by moving the pin members 6 in the +Z direction, the speed of the driver may be measured from the Z-direction position of the substrate 2. In this case, the measurement position may be an arbitrary position on the substrate 2. Driver speed data may be collected for each processing of the substrate 2, and the timing of stopping the gas supply from the supply mechanism SM or lowering the supply pressure may be decided based on the collected past data.

The controller 100 can decide the timing of stopping the first supply based on the acceleration of the driver. The acceleration may be obtained from the speed of the fine moving stage 4 or the substrate chuck 3. Also, an accelerometer may be installed in the driver, and the acceleration may be measured by the accelerometer. When the substrate 2 and the substrate chuck 3 adhere to each other so that they are difficult to separate in the early stage of the fourth section, the acceleration of the fine moving stage 4 can be lower than when they do not adhere to each other. Therefore, for example, the acceleration when the fourth section starts is measured in advance while there is no chucking force between the substrate 2 and the substrate chuck 3, and the obtained value is used as a reference value. If the acceleration after the fourth section starts is lower than the reference value, this means that the chucking force between the substrate 2 and the substrate chuck 3 was not eliminated by the gas supply in the third section. In this case, the timing of stopping the gas supply or lowering the supply pressure in the third section may be set late in the next and subsequent substrate processing. To the contrary, if the acceleration after the fourth section starts is equal to or higher than the reference value, this means that the pressure between the substrate 2 and the substrate chuck 3 was made equal to or higher than atmospheric pressure by the gas supply in the third section. In this case, the timing of stopping the gas supply or lowering the supply pressure in the third section may be set early in the next and subsequent substrate processing. Driver acceleration data may be collected for each processing of the substrate 2, and the timing of stopping the gas supply from the supply mechanism SM or lowering the supply pressure may be decided based on the collected past data.

The controller 100 can decide the timing of stopping the first supply based on the load applied on the pin member. As shown in FIGS. 13A and 13B, in an example, a load sensor 13 for detecting the load applied on the pin member 6 is arranged in the distal end of the pin member 6. For example, the load applied on the load sensor 13 when the fourth section starts is measured in advance while there is no chucking force between the substrate 2 and the substrate chuck 3, and the obtained value is used as a reference value. If the load after the fourth section starts is lower than the reference value, the timing of stopping the gas supply or lowering the supply pressure in the third section may be set late in the next and subsequent substrate processing. To the contrary, if the load after the fourth section starts is equal to or higher than the reference value, the timing of stopping the gas supply or lowering the supply pressure in the third section may be set early in the next and subsequent substrate processing. Data of the load applied on the pin member 6 may be collected for each processing of the substrate 2, and the timing of stopping the gas supply from the supply mechanism SM or lowering the supply pressure may be decided based on the collected past data.

The controller 100 can decide the moving speed of the driver in the fourth section (third period) based on at least one of the gas supply amount in the third section (second period), the start timing of the first supply, and the end timing of the first supply. When the timing of stopping the gas supply or lowering the supply pressure is late, the amount of gas supplied to the space 61 between the substrate 2 and the substrate chuck 3 increases, and this leads to a high pressure of the space 61 and a low chucking force between the substrate 2 and the substrate chuck 3. Hence, the relative moving speed between the fine moving stage 4 and the pin members 6 (the moving speed of the driver) in each of the fourth section and the fifth section may be increased. To the contrary, when the timing of stopping the gas supply or lowering the supply pressure is early, this leads to a low pressure of the space 61 and a high chucking force between the substrate 2 and the substrate chuck 3. Hence, the relative moving speed between the fine moving stage 4 and the pin members 6 (the moving speed of the driver) in each of the fourth section and the fifth section may be decreased.

The gas supply amount from the supply mechanism SM may be decided based on at least two of a plurality of characteristics described above. Examples of the plurality of characteristics described above are listed below:

the pressure of the space 61,

the volume of the space 61,

the deformation amount of the substrate 2,

the material of the substrate 2,

the roughness of the back surface of the substrate 2,

the kind of film formation on the surface of the substrate 2,

the thickness of the substrate 2,

the material of the substrate chuck 3,

the driving force of the driver or the drive current value in the driver,

the control deviation by the driver,

the moving speed of the driver,

the acceleration of the driver, and

the load applied on the pin member 6.

Also, data of at least one or more of these characteristics may be collected for each substrate processing, and the gas supply amount from the supply mechanism SM may be decided based on the results of calculation processing performed on the collected past data.

### Second Embodiment

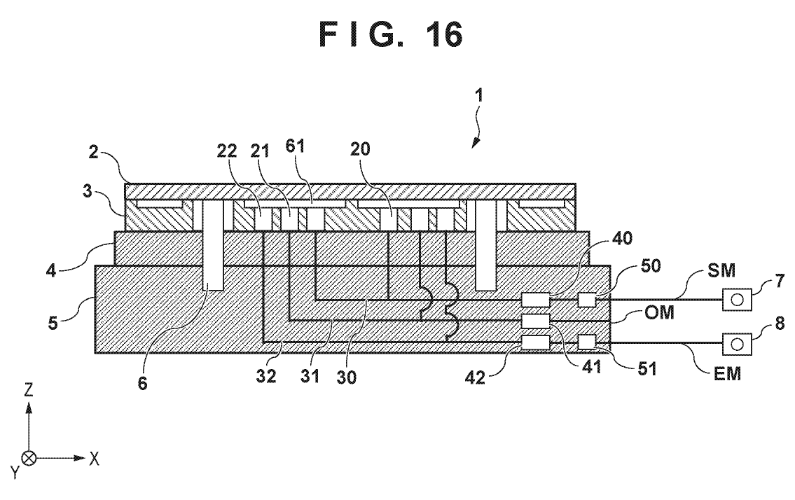

FIG. 16 shows the configuration of a substrate stage 1 according to the second embodiment. The substrate stage 1 includes an open mechanism OM that can be controlled independently and opens a space 61 to the atmosphere, separate from an exhaust mechanism EM and a supply mechanism SM. In an operation of separating a substrate 2 and a substrate chuck 3 by a driver, a controller 100 can further control opening and closing of the open mechanism OM.

The open mechanism OM is a mechanism for causing the space 61 (first space) to communicate with a stage space, and includes a flow path (pipe) 31 (second flow path) and a solenoid valve 41 (second valve).

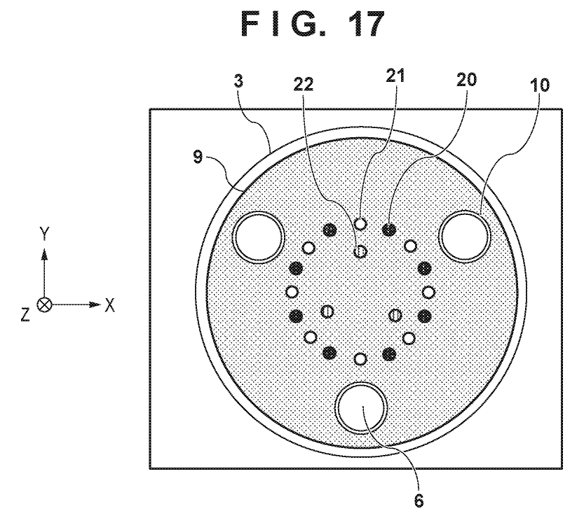

FIG. 17 is a plan view of the substrate chuck 3 when viewed from the +Z direction. In FIG. 17, a supply hole 20 continuous with a flow path 30, an exhaust hole 22 continuous with a flow path 32, and an exhaust hole 21 continuous with the flow path 31 are formed in the substrate chuck 3.

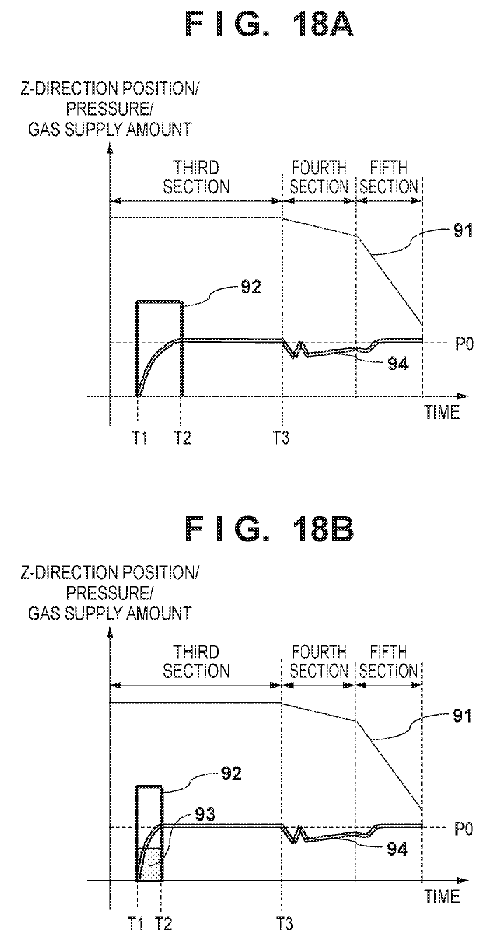

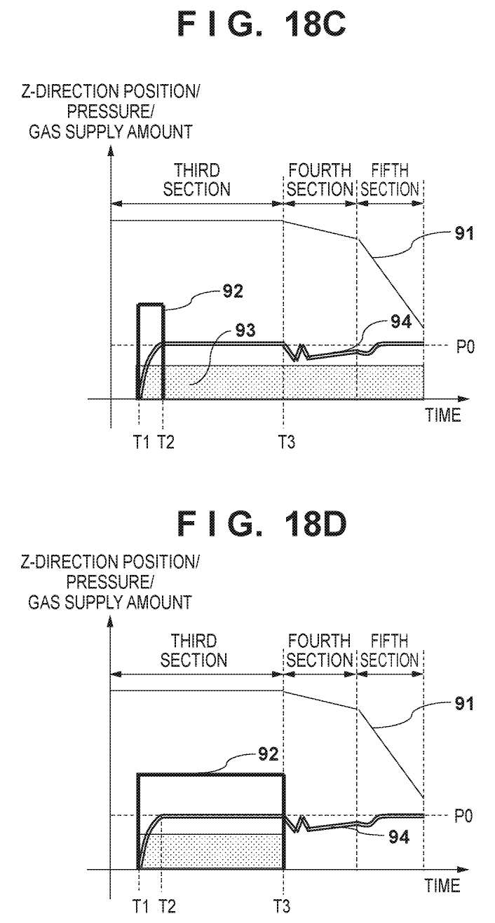

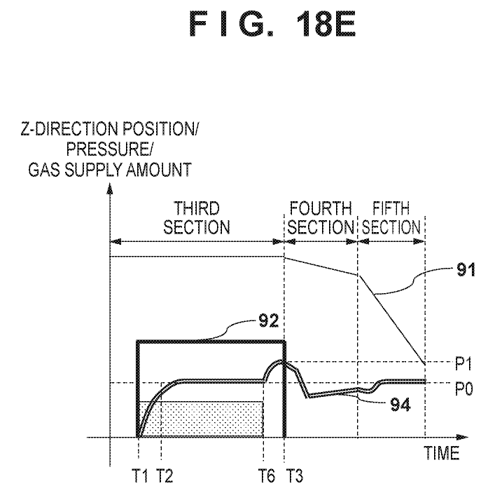

FIGS. 18A to 18E are views each showing a substrate unload profile in a case of using the open mechanism OM. A solid line 91 represents the Z-direction relative position between a fine moving stage 4 and a pin member 6, a solid line 92 represents the gas supply amount from the supply mechanism SM to the space 61, a double line 94 represents the pressure of the space 61, and hatching 93 represents that the open mechanism OM is in an open state. FIG. 18A shows a case where the open mechanism OM is not opened. FIG. 18B shows a case where the open mechanism OM is opened simultaneously with the start of the gas supply. The controller 100 can open the open mechanism OM in time with the start timing of the first supply. By simultaneously performing the gas supply (first supply) by the supply mechanism SM and the releasing by the open mechanism OM, the vacuum state of the space 61 can be rapidly opened. Consequently, time T2 when the space 61 reaches atmospheric pressure comes early. In this case, the timing of closing (turning off) the open mechanism OM may coincide with the timing of stopping the gas supply from the supply mechanism SM or lowering the supply pressure, as shown in FIG. 18B. That is, the controller 100 can close the open mechanism OM in time with the end timing of the first supply. Also, the timing of closing (turning off) the open mechanism OM may be later than the timing of stopping the gas supply or lowering the supply pressure, as shown in FIG. 18C. That is, the controller 100 can keep the open state of the open mechanism OM even in the fourth and subsequent section (third period).

Also, as shown in FIG. 18D, in the third section (second period), even after the space 61 reaches atmospheric pressure, the gas supply from the supply mechanism SM may be continued and the open state of the open mechanism OM may be kept. Until the space 61 reaches atmospheric pressure, the gas is supplied from both the supply mechanism SM and the open mechanism OM. However, once the space 61 reaches atmospheric pressure, a flow occurs in which the gas supplied from the supply mechanism SM is exhausted from the open mechanism OM. Accordingly, it is difficult for the pressure of the space 61 to rise to and above atmospheric pressure. Hence, this can be effective in suppressing the lateral shift of the substrate 2 due to the excess pressure of the space 61.

Also, as shown in FIG. 18E, the open mechanism OM may be closed before the timing of stopping the gas supply from the supply mechanism SM or lowering the supply pressure, that is, before the end timing of the first supply. At time T6 in FIG. 18E, when the open mechanism OM is closed, the flow in which the gas supplied from the supply mechanism SM is exhausted through the open mechanism OM is stopped, and the pressure of the space 61 rises above atmospheric pressure. Thus, at time T3 when the fourth section starts, the space 61 reaches a pressure P1 higher than atmospheric pressure. This can be effective for canceling the negative pressure generated by adhesion between the substrate 2 and the substrate chuck 3 in the early stage of the fourth section.

### Embodiment of Article Manufacturing Method

An article manufacturing method according to an embodiment is suitable for manufacturing an article, for example, a microdevice such as a semiconductor device or an element having a microstructure. The article manufacturing method according to the present embodiment can include a forming step of forming an original plate pattern onto a substrate by using the above-described substrate processing apparatus (lithography apparatus) and a processing step of processing the substrate on which the pattern is formed in the forming step. The manufacturing method further can include other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

According to the various embodiments described above, it is possible to provide techniques advantageous in terms of suppression of the lateral shift of a substrate and the wear resistance of a substrate chuck regarding cancellation of the holding of the substrate by the substrate chuck.

While the present disclosure has described example embodiments, it is to be understood that some embodiments are not limited to the disclosed embodiments. The scope of the following claims is to be accorded the broadest interpretation so as to encompass all such modifications and equivalent structures and functions.

This application claims priority to Japanese Patent Application No. 2025-012293, which was filed on January 28, 2025 and which is hereby incorporated by reference herein in its entirety.

What is claimed is:

1. A stage apparatus comprising:
a substrate chuck configured to support a substrate;
a supplier configured to supply a gas to a space between the substrate and the substrate chuck;
a pin member configured to support the substrate by protruding from a hole formed in the substrate chuck;
a driver configured to move at least one of the substrate chuck and the pin member; and
a controller configured to control the driver and the supplier based on a control profile,
wherein
the control profile includes a first period during which, from a state in which the substrate is placed on the substrate chuck, the driver drives so as to make the pin member protrude from the hole and approach the substrate, a second period during which, after the first period, the driver stops in a state in which the substrate and the pin member are close, and a third period during which, after the second period, the driver drives so as to separate the substrate and the substrate chuck, and
the controller starts first supply of gas by the supplier in the second period, and terminates the first supply by reducing a supply amount of gas from the supplier before the second period ends.

2. The stage apparatus according to claim 1, wherein
reducing the supply amount of gas includes stopping the supply of the gas.

3. The stage apparatus according to claim 1, wherein
in the second period, after the first supply is terminated, the controller starts second supply of gas by the supplier.

4. The stage apparatus according to claim 3, wherein
the controller terminates the second supply before a transition to the third period.

5. The stage apparatus according to claim 3, wherein
the controller terminates the second supply after a transition to the third period.

6. The stage apparatus according to claim 3, wherein
a gas supply amount in the second supply is different from a gas supply amount in the first supply.

7. The stage apparatus according to claim 3, wherein
when starting and stopping gas supply in each of the first supply and the second supply, the controller gradually changes a gas supply amount in accordance with an elapse of time.

8. The stage apparatus according to claim 1, wherein
the controller decides a timing of stopping the first supply based on at least one of a pressure of the space, a volume of the space, a deformation amount of the substrate, a material of the substrate, a roughness of a back surface of the substrate, a kind of film formation on a surface of the substrate, a thickness of the substrate, a material of the substrate chuck, a driving force of the driver, a drive current value in the driver, a control deviation by the driver, a moving speed of the driver, an acceleration of the driver, and a load applied on the pin member.

9. The stage apparatus according to claim 1, wherein
the controller decides a moving speed of the driver in the third period based on at least one of a gas supply amount in the second period, a start timing of the first supply, and an end timing of the first supply.

10. The stage apparatus according to claim 1, further comprising
an open mechanism configured to open the space to the atmosphere,
wherein the controller further controls opening and closing of the open mechanism based on the control profile.

11. The stage apparatus according to claim 10, wherein
the controller opens the open mechanism in time with a start timing of the first supply.

12. The stage apparatus according to claim 11, wherein
the controller closes the open mechanism in time with an end timing of the first supply.

13. The stage apparatus according to claim 11, wherein
the controller keeps an open state of the open mechanism even in the third period.

14. The stage apparatus according to claim 11, wherein
in the second period, the controller keeps an open state of the open mechanism even after a pressure of the space reaches atmospheric pressure.

15. The stage apparatus according to claim 11, wherein
in the second period, the controller closes the open mechanism before an end timing of the first supply.

16. A substrate processing apparatus comprising
the stage apparatus according to claim 1,
wherein the substrate held by the stage apparatus is processed.

17. The substrate processing apparatus according to claim 16, wherein
the substrate processing apparatus is a lithography apparatus configured to form a pattern on a substrate.

18. An article manufacturing method comprising:
forming a pattern on a substrate using the substrate processing apparatus defined in claim 17; and
processing the substrate on which the pattern is formed,
wherein an article is manufactured from the processed substrate.

19. A control method of a stage apparatus including a substrate chuck configured to support a substrate, a supplier configured to supply a gas to a space between the substrate and the substrate chuck, a pin member configured to support the substrate by protruding from a hole formed in the substrate chuck, and a driver configured to move at least one of the substrate chuck and the pin member, the method comprising:
controlling the driver and the supplier based on a control profile,
wherein
the control profile includes a first period during which, from a state in which the substrate is placed on the substrate chuck, the driver drives so as to make the pin member protrude from the hole and approach the substrate, a second period during which, after the first period, the driver stops in a state in which the substrate and the pin member are close, and a third period during which, after the second period, the driver drives so as to separate the substrate and the substrate chuck, and
the controlling includes
starting first supply of gas by the supplier in the second period, and
terminating the first supply by reducing a supply amount of gas from the supplier before the second period ends.
